(19) United States
(12) Patent Application Publication
(10) Pub. No.: US 2026/0150523 A1
(43) Pub. Date: May 28, 2026

(54) DISPLAY PANEL AND DISPLAY DEVICE

(71) Applicant: Yungu (Gu’an) Technology Co., Ltd., Langfang (CN)

(72) Inventors: Zhimin YAN, Langfang (CN); Fuxing JIAO, Langfang (CN)

(73) Assignee: Yungu (Gu’an) Technology Co., Ltd., Langfang (CN)

(21) Appl. No.: 19/452,899

(22) Filed: Jan. 20, 2026

Related U.S. Application Data
(63) Continuation of application No. PCT/CN2024/075036, filed on Jan. 31, 2024.

(30) Foreign Application Priority Data
Jul. 20, 2023 (CN) 202310894307.X

(51) Int. Cl. H10K 59/122; H10K 50/115; H10K 59/173; H10K 59/80

(52) U.S. Cl. CPC H10K 59/122; H10K 50/115; H10K 59/173; H10K 59/873

(57) ABSTRACT

The present application discloses a display panel and a display device. The display panel includes a substrate, a first electrode layer, a first functional layer, a light-emitting layer, a second functional layer, and a bank structure. The bank structure includes a limiting structure, a plurality of pixel openings provided in the limiting structure and accommodating the plurality of light-emitting structures, and accommodation openings provided in the limiting structure and located between adjacent light-emitting structures. The accommodation openings are configured to accommodate portions of the first functional layer located between adjacent pixel openings and portions of the second functional layer located between adjacent pixel openings, and the first functional layer and the second functional layer located within the accommodation openings are in direct contact. The display panel provided by the present application can improve display uniformity of the display panel, thereby enhancing user experience.

### CROSS-REFERENCE TO RELATED APPLICATIONS

The present application a continuation of International Application No. PCT/CN2024/075036 filed on Jan. 31, 2024, which claims priority to Chinese Patent Application No. 202310894307.X, filed on Jul. 20, 2023. All of the aforementioned patent applications are hereby incorporated by reference in their entireties.

### FIELD

The present application belongs to the field of display technology, and particularly relates to a display panel and a display device.

### BACKGROUND

With the development of display technology, the performance requirements for display devices are becoming increasingly higher. Quantum dot light-emitting diodes (QLEDs) have advantages such as high color gamut, long lifespan, good viewing angle, and low cost, making them a highly promising future display technology. However, existing display panels using quantum dot light-emitting diodes suffer from poor display uniformity.

### SUMMARY

Embodiments of the present application provide a display panel and a display device, which can improve the display uniformity of the display panel, thereby enhancing user experience.

An embodiment of the present application provides a display panel, including:

a substrate;

a first electrode layer, located on one side of the substrate and including a plurality of spaced first electrodes;

a first functional layer, a light-emitting layer, and a second functional layer sequentially stacked in a direction away from the substrate, the light-emitting layer including a plurality of light-emitting structures; and

a barrier structure, including a defining structure, a plurality of pixel openings provided in the defining structure for accommodating the plurality of light-emitting structures, and accommodating openings provided in the defining structure and located between adjacent light-emitting structures, the accommodating openings being configured to accommodate portions of the first functional layer located between adjacent pixel openings and portions of the second functional layer located between adjacent pixel openings, and the first functional layer and the second functional layer within the accommodating openings being in direct contact with each other.

An embodiment of the second aspect of the present application further provides a display device, including any one of the display panels provided in the first aspect of the present application.

The display panel provided in the present application includes a substrate, a first electrode layer, a first functional layer, a light-emitting layer, a second functional layer, and a barrier structure. The first electrode layer, the first functional layer, the light-emitting layer, and the second functional layer are sequentially stacked in a direction away from the substrate. The first electrode layer includes a plurality of spaced first electrodes. The light-emitting layer includes a plurality of light-emitting structures. The barrier structure is formed on a side of the first electrode layer away from the substrate and includes a defining structure, a plurality of pixel openings, and a plurality of accommodating openings. The plurality of pixel openings accommodate the plurality of light-emitting structures. The accommodating openings are configured to accommodate portions of the first functional layer located between adjacent first electrodes and portions of the second functional layer located between adjacent first electrodes. The first functional layer and the second functional layer within the accommodating openings are in contact with each other. The first functional layer and the second functional layer can be prepared using a wet coating process. In the coating process, ink falling between adjacent light-emitting structures can be accommodated by the accommodating openings, which reduces or eliminates variations in ink flow between pixel openings, improving film thickness uniformity within the openings and across the display panel, which enhances display performance. The process is straightforward and cost-effective.

### BRIEF DESCRIPTION OF THE DRAWINGS

FIG. 1 is a partial schematic diagram of a display panel provided by an embodiment of the present application;

FIG. 2 is a cross-sectional view taken along line P-P' in FIG. 1;

FIG. 3 is another cross-sectional view taken along line P-P' in FIG. 1;

FIG. 4 is another cross-sectional view taken along line P-P' in FIG. 1;

FIG. 5 is another cross-sectional view taken along line P-P' in FIG. 1;

FIG. 6 is a partial schematic diagram of another display panel provided by an embodiment of the present application;

FIG. 7 is a partial schematic diagram of another display panel provided by an embodiment of the present application;

FIG. 8 is a partial schematic diagram of another display panel provided by an embodiment of the present application;

FIG. 9 is a partial schematic diagram of another display panel provided by an embodiment of the present application;

FIG. 10 is a partial schematic diagram of another display panel provided by an embodiment of the present application;

FIG. 11 is a partial schematic diagram of another display panel provided by an embodiment of the present application;

FIG. 12 is a cross-sectional view taken along line M-M' in FIG. 11;

FIG. 13 is another cross-sectional view taken along line P-P' in FIG. 1;

FIG. 14 is a structural schematic diagram of a display device provided by an embodiment of the present application.

### DETAILED DESCRIPTION

The inventors have found through research that one preparation process for display panels using quantum dot light-emitting diodes is a wet coating process. However, since the wet coating process is a full-surface film-forming process, ink(e.g., a functional material or ink used in the manufacturing process) spreads entirely over the substrate, and ink on the pixel defining layer flows into the pixel openings. Due to the randomness of ink flow, the ink volumes in the left and right sub-pixels differ, leading to film thickness variations, which significantly impacts the performance of the final device and the uniformity of the display panel's display effect. Based on research into the above problems, the inventors provide a display panel and a display device to improve the display uniformity of the display panel.

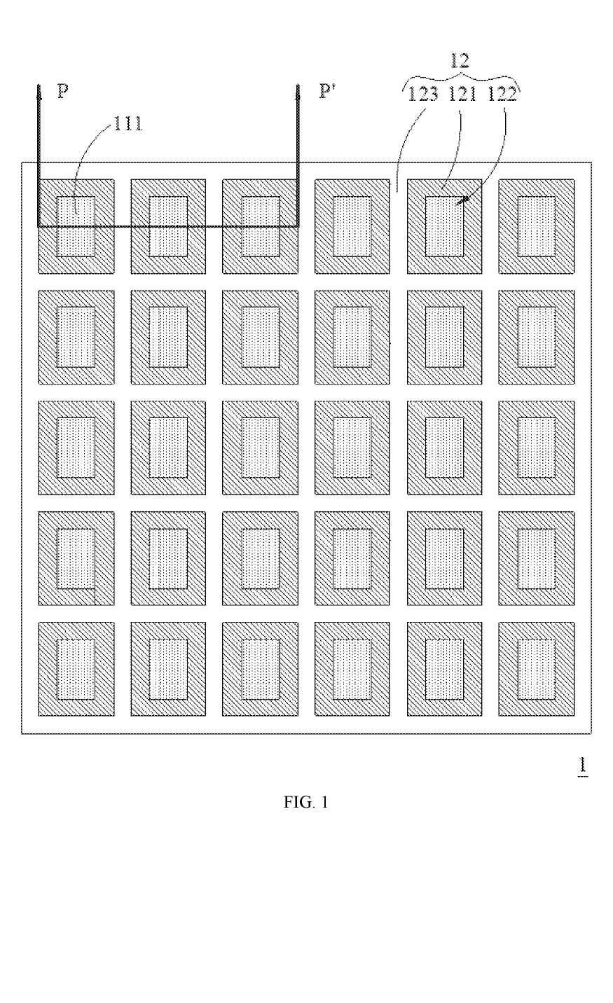

To better understand the present application, the display panel and display device according to the embodiments of the present application will be described in detail below with reference to FIGS. 1-14.

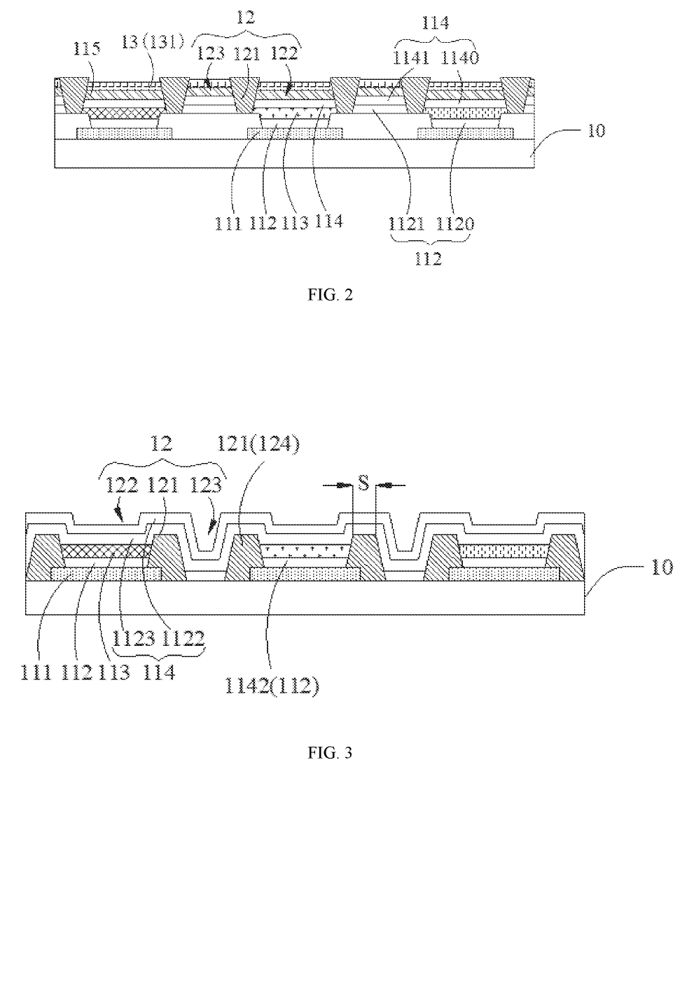

Referring to FIG. 1 and FIG. 2, an embodiment of the present application provides a display panel 1, including a substrate 10, a first electrode layer, a first functional layer 112, a light-emitting layer, a second functional layer 114, and a barrier structure 12. The first electrode layer is located on one side of the substrate 10 and includes a plurality of first electrodes 111 spaced apart. The first functional layer 112, the light-emitting layer, and the second functional layer 114 are sequentially stacked in a direction away from the substrate 10, and the light-emitting layer includes a plurality of light-emitting structures 113. The barrier structure 12 includes a defining structure 121, a plurality of pixel openings 122 disposed in the defining structure 121 and accommodating the plurality of light-emitting structures 113, and a plurality of accommodating openings 123 disposed in the defining structure 121 and located between adjacent light-emitting structures 113. The accommodating openings 123 are configured to accommodate portions of the first functional layer 112 located between adjacent pixel openings 122 and portions of the second functional layer 114 located between adjacent pixel openings 122, and the first functional layer 112 and the second functional layer 114 within the accommodating openings 123 are in direct contact.

The display panel 1 provided in the present application includes the substrate 10, the first electrode layer, the first functional layer 112, the light-emitting layer, the second functional layer 114, and the barrier structure 12. The first electrode layer is located on one side of the substrate, and the first functional layer 112, the light-emitting layer, and the second functional layer 114 are sequentially stacked in a direction away from the substrate. The first electrode layer includes a plurality of first electrodes 111 spaced apart. The light-emitting layer includes a plurality of light-emitting structures 113. The barrier structure 12 is formed on a side of the first electrode layer away from the substrate 10 and includes the defining structure 121, the plurality of pixel openings 122, and the plurality of accommodating openings 123. The plurality of pixel openings accommodate the plurality of light-emitting structures 113. The accommodating openings 123 are configured to accommodate portions of the first functional layer 112 located between adjacent first electrodes 111 and portions of the second functional layer 114 located between adjacent first electrodes 111. The first functional layer 112 and the second functional layer 114 within the accommodating openings 123 contact each other. The first functional layer 112 and the second functional layer 114 can be prepared using a wet coating process. In the coating process, ink falling between adjacent light-emitting structures 113 can be accommodated by the accommodating openings 123, thereby reducing the probability of the ink flowing towards sides of the two light-emitting structures 113 away from the substrate 10 (i.e., into the pixel openings 122). This reduces or eliminates differences in ink flow amounts within different pixel openings 122, thereby enhancing the uniformity of film thickness within the pixel openings 122, making the thickness of various regions of the display panel 1 more uniform. This helps improve the display uniformity of the display panel 1, thereby enhancing user experience, and the preparation process is simple and low-cost.

As shown in FIG. 3, the pixel openings 122 are configured to expose partial areas of the first electrodes 111. An orthographic projection of the defining structure 121 on the substrate 10 covers edge portions of orthographic projections of the first electrodes 111 on the substrate 10.

The pixel openings 122 are configured to expose partial areas of the first electrodes 111 to facilitate light emission from the light-emitting structures 113. The orthographic projection of the defining structure 121 on the substrate 10 covers the edge portions of the orthographic projections of the first electrodes 111 on the substrate 10. This, on one hand, enables mutual insulation between adjacent first electrodes 111, and on the other hand, provides a protective effect for the first electrodes 111, preventing the edges of the first electrodes 111 from being exposed and affecting their performance.

In a feasible embodiment, as shown in FIG. 3, the defining structure 121 includes a first defining structure 124. The accommodating openings 123 expose partial areas of the substrate 10 located between adjacent first electrodes 111.

In the above embodiment, a pixel definition layer in the display panel 1 is omitted, and the defining structure 121 is used to define the pixels (light-emitting structures 113). The defining structure 121 includes a single layer. The accommodating openings 123 penetrate through the defining structure 121 along its thickness direction and expose the substrate 10, thereby maximizing the volume of the accommodating openings 123 within the constraints of the defining structure 121's overall dimensions to accommodate more ink. The accommodating openings 123 are configured to accommodate the first functional layer and/or the second functional layer prepared by a wet coating process, and portions of these layers located between adjacent first electrodes 111 are contained within the openings, minimizing flow and thereby improving film thickness uniformity within the display panel 1.

In the above embodiment, the preparation method for the barrier structure 12 is simple, can be performed using conventional preparation processes for the display panel 1, and omits the pixel definition layer. Changing to the barrier structure 12 does not significantly increase the number of process steps, enabling low-cost preparation.

In the above embodiment, a minimum distance between a side of the first defining structure 124 close to the pixel openings 122 and a side away from the pixel openings 122 is S, and S < 5 µm. In one embodiment, S can be 1.5 µm, 2 µm, 2.3 µm, 3.4 µm, 3.8 µm, 4.2 µm, 4.9 µm, which is not particularly limited in the present application. Selecting the above dimensions can, on one hand, meet the requirement for spacing between adjacent light-emitting structures 113, and on the other hand, satisfy the precision limitations of the preparation process for the barrier structure 12.

In one embodiment, S < 2 µm. In one embodiment, S can be 0.5 µm, 1 µm, 1.3 µm, 1.4 µm, 1.8 µm, 1.9 µm. This can reduce the occupancy rate of the barrier structure 12 in the region between adjacent light-emitting structures 113, thereby further reducing the spacing between the light-emitting structures 113. Consequently, the aperture ratio of the display panel 1 can be improved, enhancing the display effect.

In the above embodiment, the material of the first defining structure 124 includes at least one of polyimide, epoxy resin, acrylic resin, silicone resin, silicon nitride, silicon oxide, and fluorine-containing compounds. In one embodiment, the fluorine-containing compound is a compound including perfluoromethyl, perfluoroethyl, or perfluorophenyl, or a derivative of a compound including perfluoromethyl, perfluoroethyl, or perfluorophenyl. The above materials are readily available and low-cost, making them suitable for use as the material for the barrier structure 12.

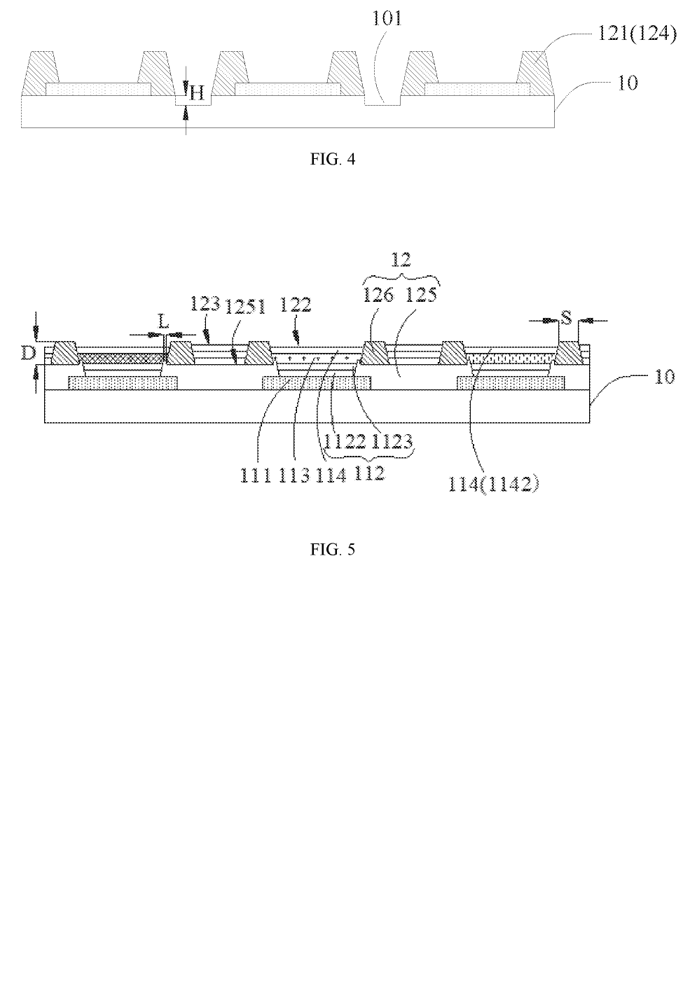

In the above embodiments, the material of the first limiting structure 124 is a hydrophobic material, which may in one embodiment be perfluoromethyl-, perfluoroethyl- or perfluorophenyl-substituted compounds. Using a hydrophobic material can reduce the probability of ink residue on the bank structure 12, thereby improving film thickness non-uniformity caused by varying amounts of ink residue on the sidewalls of the pixel opening 122. In a feasible embodiment, as shown in FIG. 4, the region of the substrate 10 opposite to the accommodation opening 123 further includes a groove portion 101. The orthographic projection of the limiting structure 121 on the substrate 10 does not overlap with the groove portion 101. The thickness of the groove portion 101 in a direction perpendicular to the substrate 10 is H, and 0 μm < H ≤ 10 μm.

In the above embodiments, the groove portion 101 is formed by recessing from the surface of the substrate 10 facing the bank structure 12 toward the surface of the substrate 10 away from the bank structure 12. It means the groove portion 101 is formed by recessing into the substrate 10 from the surface facing the bank structure 12. Forming the groove portion 101 on the substrate 10 can further increase the ink capacity of the bank structure 12 for the first functional layer and/or the second functional layer, reducing the probability of ink overflowing from the accommodation opening 123 and flowing into the pixel opening 122, thereby further improving the uniformity of the film thickness inside the pixel opening 122. In one embodiment, the orthographic projections of the groove portion 101 and the limiting structure 121 on the substrate 10 do not overlap, thereby ensuring good support of the limiting structure 121 by the substrate 10, enhancing the connection stability between them, and avoiding instability in the connection due to the limiting structure 121 being located on the groove portion 101, which would result in a smaller contact area between the substrate 10 and the limiting structure 121. In one embodiment, the thickness H of the groove portion 101 in a direction perpendicular to the substrate 10 may be 0.5 μm, 0.8 μm, 1.0 μm, 1.3 μm, 1.6 μm, 2.4 μm, 2.9 μm, 3.1 μm, 3.5 μm, 3.8 μm, 4.0 μm, 4.5 μm, 5 μm, 7.2 μm, 8.4 μm, 9.6 μm, 10 μm, which is not specifically limited in this application. Using the above dimensions can avoid damage to devices within the substrate 10.

In a feasible embodiment, as shown in FIG. 5, the limiting structure 121 includes a second limiting structure 125 and a third limiting structure 126 stacked in a direction away from the substrate 10. The orthographic projection of the third limiting structure 126 on the substrate 10 is located within the orthographic projection of the second limiting structure 125 on the substrate 10. The accommodation opening 123 penetrates the third limiting structure 126 in a direction perpendicular to the substrate 10. In the above embodiment, the second limiting structure 125 may be a pixel definition layer, and the third limiting structure 126 is located on a side of the second limiting structure 125 away from the substrate 10. The second limiting structure 125 and the third limiting structure 126 are separate components that are in contact and connected. The accommodation opening 123 is formed only in the third limiting structure 126. This embodiment allows for the addition of a third limiting structure 126 without altering the original manufacturing process of the display panel 1, minimizing the impact on the manufacturing process of the display panel 1 and helping to save costs. In the above embodiments, as shown in FIG. 5, the second limiting structure 125 includes an accommodation groove 1251, and the third limiting structure 126 is located within the accommodation groove 1251. This can increase the ink capacity of the bank structure 12, including the volume of the accommodation opening 123 and the volume at the connection between the accommodation groove 1251 and the accommodation opening 123, thereby reducing the probability of ink overflowing from the accommodation opening 123 and flowing into the pixel opening 122, further improving the uniformity of the film thickness inside the pixel opening 122. In the above embodiments, the dimension of the third limiting structure 126 in a direction perpendicular to the substrate 10 is D, and 0.5 μm ≤ D ≤ 8 μm. In one embodiment, D may be 0.5 μm, 0.9 μm, 1.1 μm, 1.3 μm, 1.7 μm, 2.4 μm, 2.8 μm, 3.1 μm, 3.3 μm, 3.8 μm, 4.0 μm, 4.3 μm, 4.4 μm, 4.9 μm, 5.0 μm, 5.2 μm, 5.7 μm, 6.0 μm, 6.5 μm, 7.3 μm, 7.5 μm, 7.8 μm, 8.0 μm, etc., which is not specifically limited in this application. Using the above dimensions ensures that ink between the light-emitting structures 113 is accommodated within the accommodation opening 123 while meeting the requirement for a thinner and lighter display panel 1. In the above embodiments, D may further be in the range of 1 μm to 5 μm, i.e., 1 μm ≤ D ≤ 5 μm; it may be 1 μm, 1.1 μm, 1.3 μm, 1.4 μm, 1.5 μm, 2.4 μm, 2.9 μm, 3.1 μm, 3.5 μm, 3.8 μm, 4.1 μm, 4.3 μm, 4.8 μm, 5 μm, etc., which is not specifically limited in this application. In the above embodiments, the second limiting structure 125 includes a first end close to the third limiting structure 126, and the third limiting structure 126 includes a second end close to the second limiting structure 125. The spacing between the edge of the first end near the pixel opening 122 and the edge of the second end near the pixel opening 122 is L, and L < 2 μm. In one embodiment, L may be 0.5 μm, 0.8 μm, 1.0 μm, 1.3 μm, 1.6 μm, 1.7 μm, 1.9 μm, etc., which is not specifically limited in this application. Using the above dimensions allows the third limiting structure 126 to be located near the edge of the surface of the second limiting structure 125 away from the substrate 10. This can increase the volume of the accommodation opening 123 without changing the dimensions between the side of the third limiting structure 126 near the pixel opening 122 and the side away from the pixel opening 122, while reducing the area of the second limiting structure 125 not covered by the third limiting structure 126 and the accommodation opening 123. This lowers the probability of ink falling in this area and flowing into the pixel opening 122, further improving film thickness uniformity.

In the above embodiments, along a direction parallel to the substrate 10, the minimum distance between the side of the third limiting structure 126 close to the pixel opening 122 and the side away from the pixel opening 122 is S, and S < 5 μm. In one embodiment, S may be 0.5 μm, 0.8 μm, 1.0 μm, 1.3 μm, 1.6 μm, 2.4 μm, 2.9 μm, 3.1 μm, 3.5 μm, 3.8 μm, 4.0 μm, 4.2 μm, 4.5 μm, 4.8 μm, etc., which is not particularly limited in this application. Selecting the above dimensions can reduce the volume of the solid portion in the third limiting structure 126 under the premise of allowing preparation process accuracy, thereby increasing the volume of the accommodation opening 123.

In the above embodiments, in one embodiment, it may be further defined that S < 2 μm; it may be 0.5 μm, 0.9 μm, 1.1 μm, 1.3 μm, 1.7 μm, 1.8 μm, 1.9 μm, etc., which is not particularly limited in this application, to further increase the volume of the accommodation opening 123.

In the above embodiments, the material of the third limiting structure 126 includes at least one of polyimide, epoxy resin, acrylic resin, silicone resin, silicon nitride, silicon oxide, and fluorine-containing compounds. In one embodiment, the fluorine-containing compound is a compound including perfluoromethyl, perfluoroethyl, or perfluorophenyl, or a derivative of a compound including perfluoromethyl, perfluoroethyl, or perfluorophenyl.

In one embodiment, the material of the second limiting structure 125 may be the same as that of the third limiting structure 126, or the above materials may be selected, which is not particularly limited in this application.

In the above embodiments, the material of the third limiting structure 126 is a hydrophobic material.

In the above embodiments, the material of the third limiting structure 126 is a hydrophobic material, in one embodiment, it may be a compound containing perfluoromethyl, perfluoroethyl, or perfluorophenyl substituents. Using a hydrophobic material can reduce the probability of ink residue on the limiting structure 121 and improve film thickness non-uniformity caused by different amounts of ink residue on the sidewalls of the pixel opening 122.

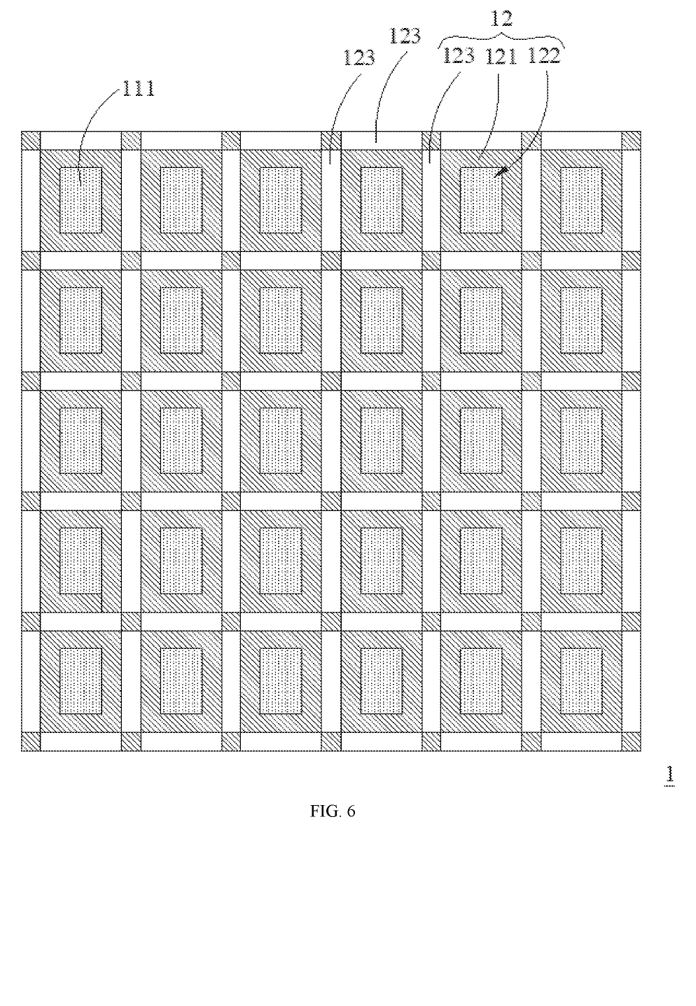

In a feasible embodiment, as shown in FIG. 6, the barrier structure 12 includes a plurality of accommodation openings 123, and the plurality of accommodation openings are interconnected.

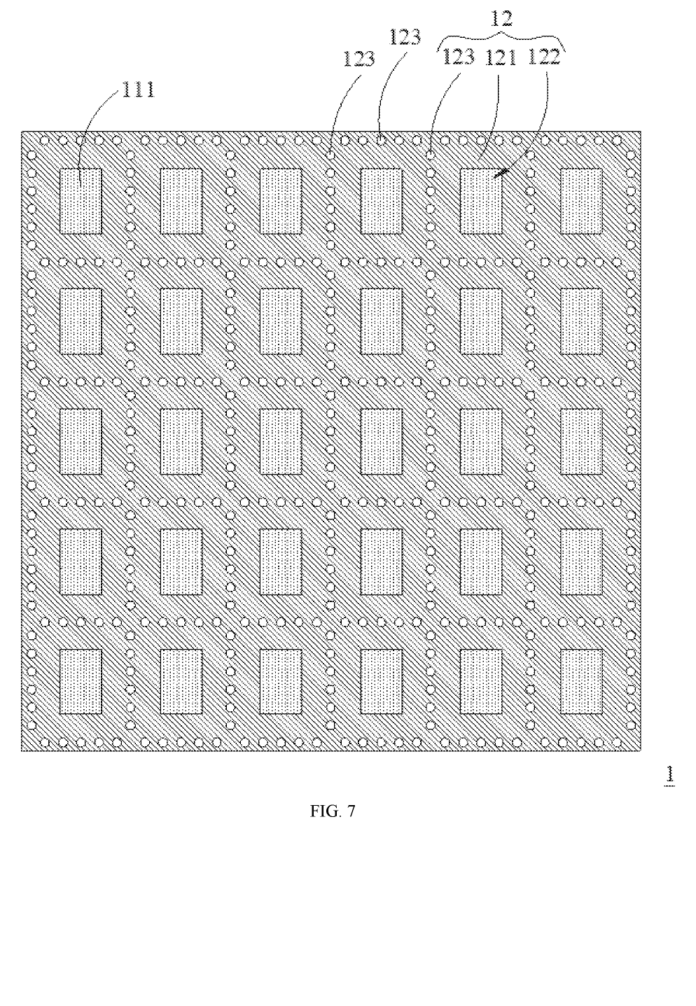

In a feasible embodiment, as shown in FIG. 7, the portion of the barrier structure 12 located between adjacent pixel openings 122 includes a plurality of accommodation openings 123, and the plurality of accommodation openings 123 are arranged around the pixel opening 122.

In the above embodiments, by providing a plurality of accommodation openings 123 in the portion of the barrier structure 12 located between adjacent first electrodes 111, the effective length or path length of the first functional layer 112 and/or the second functional layer 114 can be increased, thereby increasing the path length for lateral transmission, reducing lateral crosstalk issues, and improving light-emitting yield.

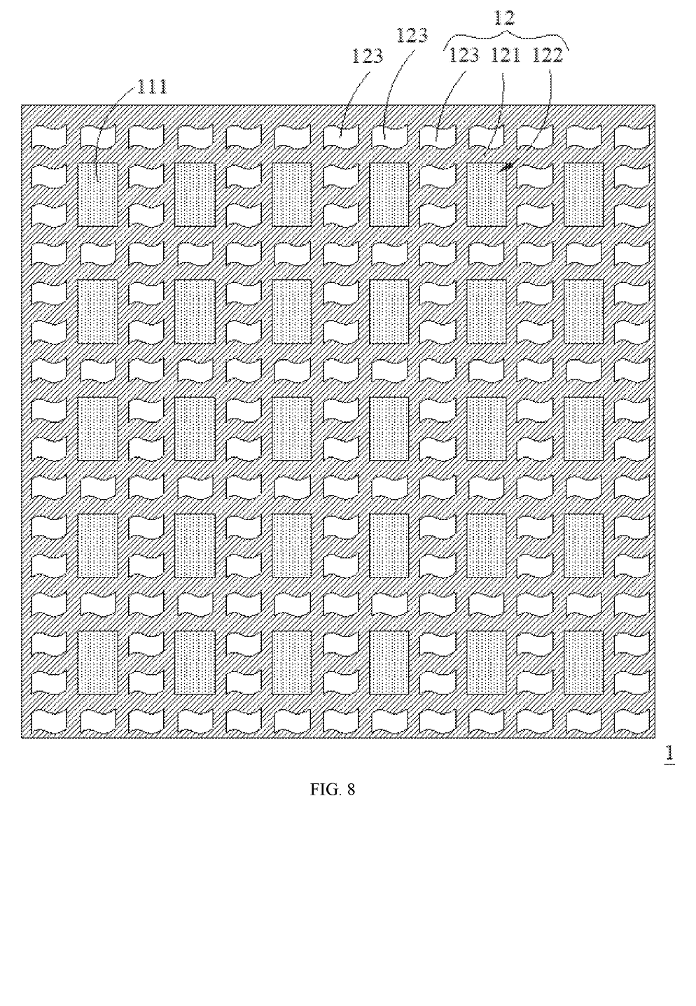

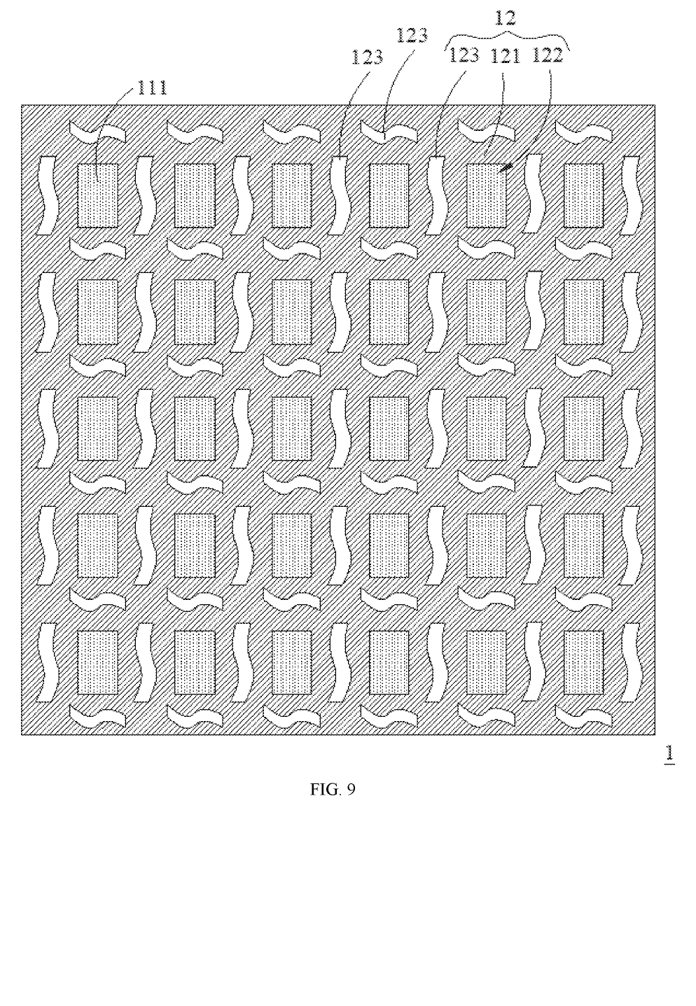

In a feasible embodiment, as shown in FIG. 7, the plurality of accommodation openings are arranged around the pixel opening, and the shape of the orthographic projection of the inner wall of the accommodation opening 123 on the substrate 10 is circular or polygonal. In one embodiment, as shown in FIG. 8 and FIG. 9, the shape of the orthographic projection of the inner wall of the accommodation opening 123 on the substrate is a preset pattern. The preset pattern includes two opposite and parallel first sides and two opposite and parallel second sides. The first sides are straight line segments, and the second sides are curved segments. The length direction of the straight line segments is parallel to the arrangement direction of adjacent pixel openings. In one embodiment, as shown in FIG. 8 and FIG. 9, there may be one or more accommodation openings 123 between adjacent pixel openings 122, which is not particularly limited in this application.

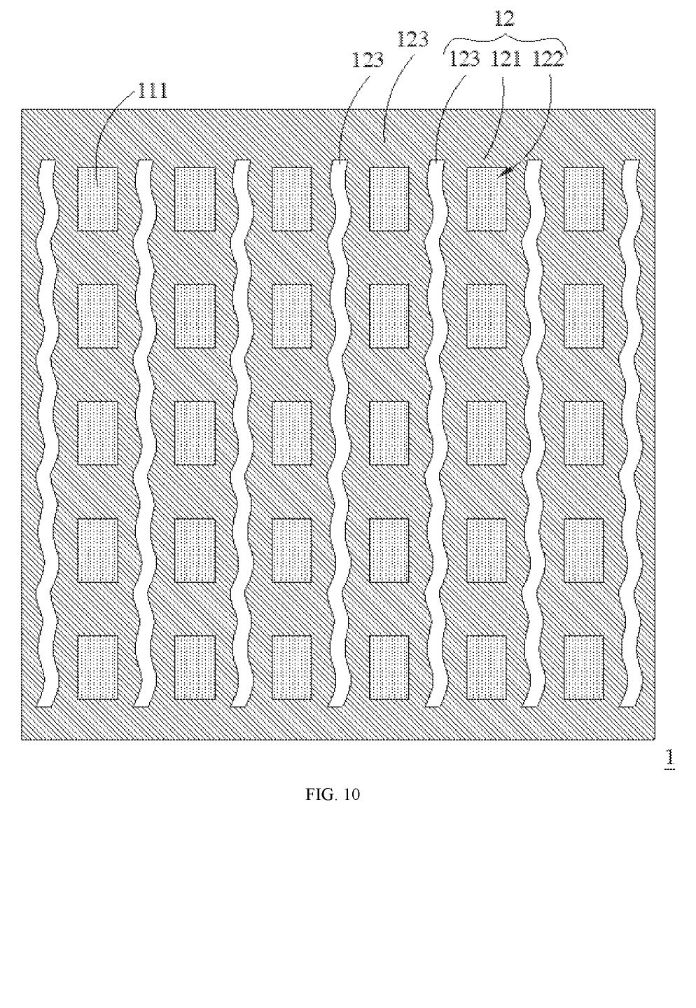

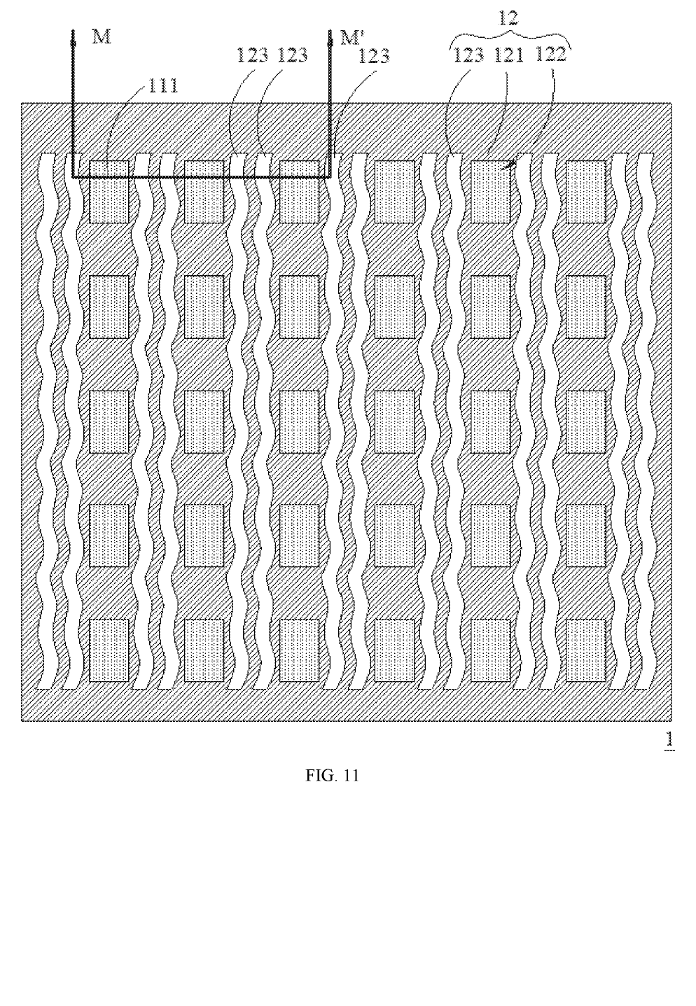

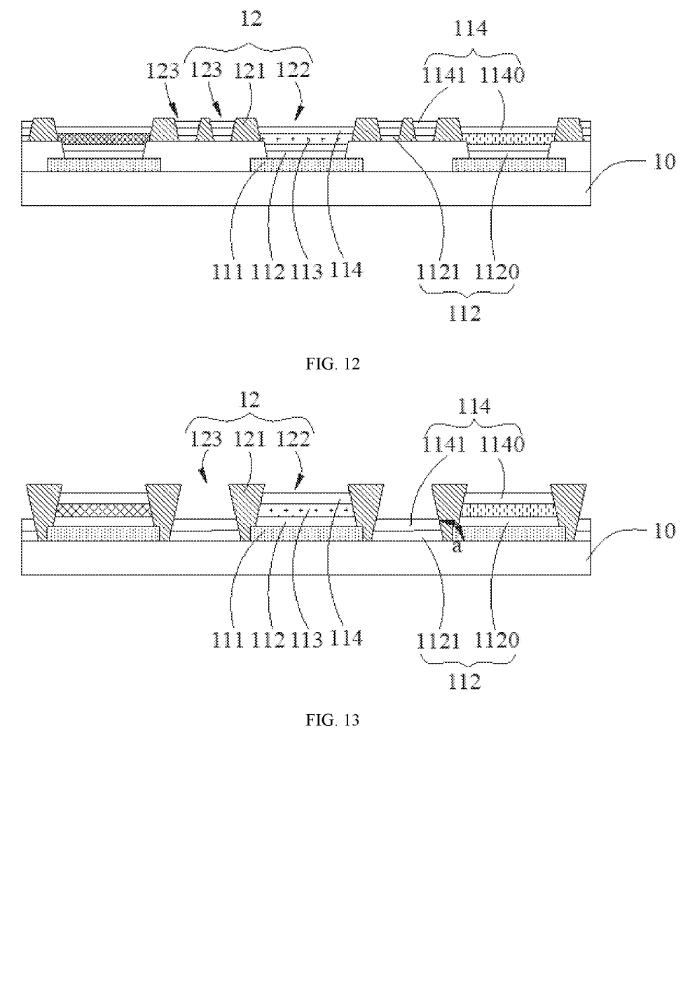

In a feasible embodiment, as shown in FIG. 10, FIG. 11, and FIG. 12, at least some of the plurality of accommodation openings 123 in the barrier structure 12 are interconnected.

In the above embodiments, at least some of the plurality of accommodation openings 123 are interconnected, allowing ink to flow within the accommodation openings 123. Ink from positions with more ink can flow to positions with less ink, reducing the probability of overflow due to excessive ink at individual positions.

In a feasible embodiment, the pixel openings are arranged in an array along a first direction and a second direction, and the plurality of accommodation openings extend along the first direction and are disposed between pixel openings adjacent along the second direction.

In a feasible embodiment, one or more of the plurality of accommodation openings are located between pixel openings adjacent along the second direction.

In a feasible embodiment, the accommodation opening extending along the first direction is provided to penetrate along the first direction, and both ends of the accommodation opening extend beyond the corresponding pixel opening.

In the above embodiments, the accommodation opening extends along the first direction, and the projection of the accommodation opening in the second direction covers the projections of at least two pixel openings in the second direction.

In a feasible embodiment, as shown in FIG. 13, the cross-sectional shape of the limiting structure 121 perpendicular to the plane of the substrate 10 is an inverted trapezoid, meaning the cross-sectional shape of the limiting structure 121 along a direction perpendicular to the plane of the substrate is an inverted trapezoid. This can reduce the probability of ink residue on the sidewalls of the accommodation opening 123 and the pixel opening 122, improving film thickness non-uniformity caused by different amounts of residue on the sidewalls.

In the above embodiments, the base angle of the inverted trapezoid is a, and 90° ≤ a ≤ 150°; a may be 95°, 100°, 105°, 108°, 110°, 116°, 123°, 135°, 137°, 141°, 143°, 147°, 150°, which is not particularly limited in this application.

In a feasible embodiment, as shown in FIG. 2, the cross-sectional shape of the limiting structure 121 perpendicular to the plane of the substrate 10 is an inverted trapezoid. The display panel 1 further includes an encapsulation layer 13, which includes a plurality of spaced encapsulation portions 131. The encapsulation portion 131 contacts the sidewall of the pixel opening 122, and the orthographic projection of the encapsulation portion 131 on the substrate 10 covers the orthographic projection of the light-emitting structure 113 on the substrate 10.

The inverted trapezoid design allows the encapsulation layer 13 to be disconnected to form encapsulation portions 131. The encapsulation portions 131 can achieve independent encapsulation of the light-emitting structure 113. The encapsulation portion 131 contacts the sidewall of the pixel opening 122, thereby improving encapsulation reliability.

When the base angle of the inverted trapezoid is a, and 90° ≤ a ≤ 150°, the contact quality between the encapsulation portion 131 and the sidewall of the pixel opening 122 can be improved, further enhancing encapsulation reliability.

In another feasible embodiment, the cross-sectional shape of the limiting structure 121 perpendicular to the plane of the substrate 10 is a regular trapezoid, triangle, or quadrilateral, which is not specifically limited in this application. The use of regular shapes provides strong reliability and facilitates simulation to model the effect of the display panel 1 before its fabrication.

In a feasible embodiment, as shown in FIG. 13 and FIG. 2, the first functional layer 112 includes a first part 1120 and a second part 1121 arranged discontinuously, with the first part 1120 located within the pixel opening 122 and the second part 1121 located within the accommodating opening 123, and/or the second functional layer 114 includes a third part 1140 and a fourth part 1141 arranged discontinuously, with the third part 1140 located within the pixel opening 122 and the fourth part 1141 located within the accommodating opening 123.

In the above embodiment, the first functional layer 112 and the second functional layer 114 can be prepared using a wet coating process or by evaporation. When preparing the first functional layer using the wet coating process, the ink cannot remain on the sidewalls of the pixel opening 122, the surface of the barrier structure 12 facing away from the substrate 10, or the sidewalls of the accommodating opening 123, resulting in the first functional layer 112 including two parts: the first part 1120 and the second part 1121, with the first part 1120 located within the pixel opening 122 and the second part 1121 located within the accommodating opening 123. When preparing the second functional layer using the wet coating process, the ink cannot remain on the sidewalls of the pixel opening 122, the surface of the barrier structure 12 facing away from the substrate 10, or the sidewalls of the accommodating opening 123, resulting in the second functional layer 114 including two parts: the third part 1140 and the fourth part 1141, with the third part 1140 located within the pixel opening 122 and the fourth part 1141 located within the accommodating opening 123.

In a feasible embodiment, please refer again to FIG. 5, the first functional layer 112 includes at least one of a hole injection layer 1122, a hole transport layer 1123, and an electron blocking layer; the second functional layer 114 includes at least one of a hole blocking layer, an electron transport layer 1142, and an electron injection layer.

In a feasible embodiment, as shown in FIG. 2, the cross-sectional shape of the limiting structure 121 perpendicular to the plane of the substrate 10 is an inverted trapezoid, and the display panel further includes a second electrode 115, with the second electrode 115 located on the side of the second functional layer facing away from the substrate 10, adjacent second electrodes 115 being spaced apart, and the orthographic projection of the second electrode 115 on the substrate 10 covering the pixel opening 122.

In the above embodiment, the barrier structure 12 can separate the entire second electrode 115 layer into multiple second electrodes 115 that are isolated from each other, enabling independent control of different light-emitting structures 113. This allows adjustment of the light emission brightness of the light-emitting structures 113 in different regions according to varying brightness requirements, thereby reducing power consumption and improving the issue of uneven display brightness across different regions of the display panel 1 caused by IR-drop.

In a specific embodiment, as shown in FIG. 2, the first electrode 111 may be an anode, and the second electrode 115 may be a cathode. As shown in FIG. 5, the first functional layer 112 may include a hole injection layer 1122 and a hole transport layer 1123 stacked in a direction away from the substrate 10. The second functional layer 114 may include an electron transport layer 1142, and the light-emitting layer may be a quantum dot light-emitting layer.

In this case, the hole injection layer 1122, hole transport layer 1123, quantum dot light-emitting layer, and electron transport layer 1142 can all be prepared using a wet coating process. Therefore, these layers each include a portion located within the pixel opening 122 and a portion located within the accommodating opening 123, with the portions within the pixel opening 122 and the accommodating opening 123 being discontinuous. The side surfaces of the barrier structure 12 and the surface facing away from the substrate 10 do not form these layers. The second electrode 115 may be continuously formed across the entire device surface or consist of independent segments, which is not specifically limited in this application.

The quantum dot light-emitting layer located within the accommodating opening can be removed through the process.

In another specific embodiment, as shown in FIG. 2, the first electrode 111 may be a cathode, and the second electrode 115 may be an anode. As shown in FIG. 3, the first functional layer 112 may include an electron transport layer 1142. The second functional layer 114 may include a hole transport layer 1123 and a hole injection layer 1122 stacked in a direction away from the substrate 10, and the light-emitting layer may be a quantum dot light-emitting layer.

In this case, the electron transport layer 1142 and the quantum dot light-emitting layer can both be prepared using a wet coating process. Therefore, these layers each include a portion located within the pixel opening 122 and a portion located within the accommodating opening 123, with the portions within the pixel opening 122 and the accommodating opening 123 being discontinuous. The side surfaces of the barrier structure 12 and the surface facing away from the substrate 10 do not form these layers. The hole transport layer 1123 and the hole injection layer 1122 can be prepared using an evaporation process, allowing them to be continuously formed across the entire surface. The second electrode 115 may be continuously formed across the entire surface or be independent from each other, which is not specifically limited in this application.

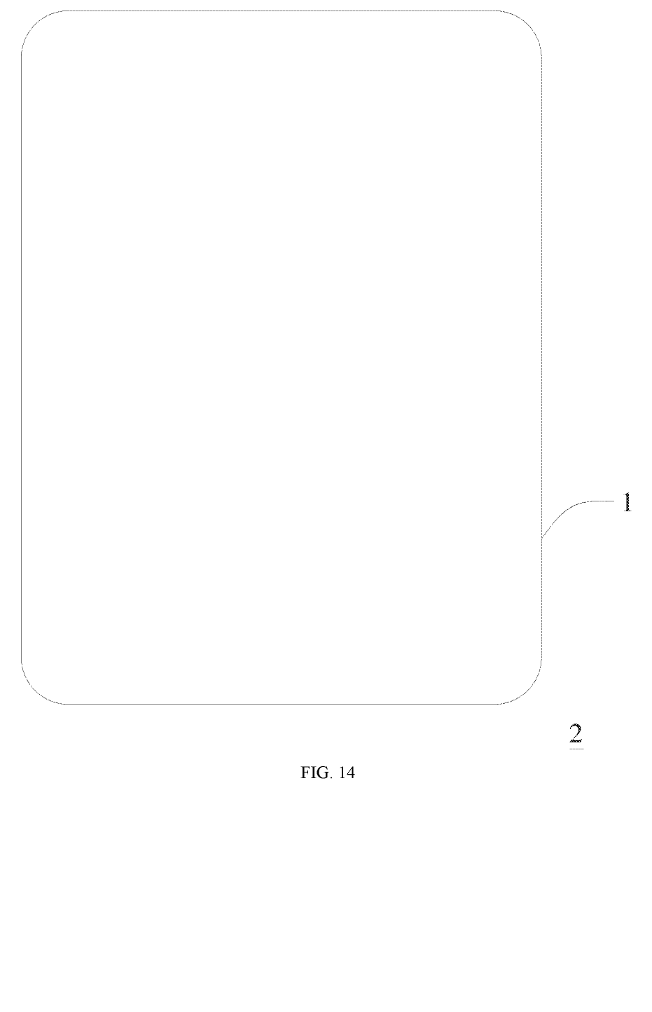

This application also provides a display device 2, as shown in FIG. 14, which includes any one of the display panels 1 provided in the above embodiments of this application.

This application also provides a display device 2, which includes any one of the display panels 1 provided in this application.

Since the display device 2 provided in this application includes any one of the display panels 1 provided in the above embodiments, the display device 2 provided in this application has the beneficial effects of any one of the display panels 1 provided in the above embodiments, which will not be repeated here.

The display device 2 in the embodiments of this application includes, but is not limited to, devices with display functions such as mobile phones, personal digital assistants (PDAs), tablet computers, e-books, televisions, access control systems, smart landline phones, and consoles.

According to the embodiments of the present application as described above, these embodiments do not exhaustively describe all details, nor do they limit the application to the specific embodiments. In one embodiment, many modifications and variations can be made based on the above description. These embodiments are selected and in one embodiment described in this specification to better explain the principles and practical applications of the present application, thereby enabling those to make good use of the present application and modifications based thereon. The present application is limited only by the claims and their full scope and equivalents.

What is claimed is:

1. A display panel, comprising:
a substrate;
a first electrode layer, located on one side of the substrate and comprising a plurality of spaced first electrodes;
a first functional layer, a light-emitting layer, and a second functional layer sequentially stacked in a direction away from the substrate, the light-emitting layer comprising a plurality of light-emitting structures; and
a bank structure, comprising a defining structure, a plurality of pixel openings provided in the defining structure and accommodating the plurality of light-emitting structures, and an accommodation opening provided in the defining structure and located between adjacent light-emitting structures, the accommodation opening being configured to accommodate a portion of the first functional layer located between adjacent pixel openings and a portion of the second functional layer located between adjacent pixel openings, and the first functional layer and the second functional layer within the accommodation opening being in direct contact.

2. The display panel according to claim 1, wherein the defining structure comprises a first defining structure, and a partial area of the substrate located between the adjacent first electrodes is exposed by the accommodating opening.

3. The display panel according to claim 2, wherein along a direction parallel to the substrate, a minimum distance between opposite sides of the first defining structure, one side being close to the pixel opening and the other side being away from the pixel opening, is S, wherein S < 5 µm.

4. The display panel according to claim 2, wherein a material of the first defining structure is a hydrophobic material.

5. The display panel according to claim 2, wherein a region of the substrate opposite to the accommodation opening further comprises a recessed portion, an orthographic projection of the defining structure on the substrate does not overlap with the recessed portion, and a thickness of the recessed portion along a direction perpendicular to the substrate is H, wherein 0 µm < H ≤ 10 µm.

6. The display panel according to claim 1, wherein the defining structure comprises a second defining structure and a third defining structure sequentially stacked in a direction away from the substrate, an orthographic projection of the third defining structure on the substrate is located within an orthographic projection of the second defining structure on the substrate, and the accommodation opening penetrates through the third defining structure along a direction perpendicular to the substrate.

7. The display panel according to claim 6, wherein the second defining structure comprises an accommodation groove, and the third defining structure is located within the accommodation groove.

8. The display panel according to claim 6, wherein a dimension of the third defining structure along a direction perpendicular to the substrate is D, where 0.5 µm ≤ D ≤ 8 µm; and a minimum distance between opposite sides of the third defining structure, one side being close to the pixel opening and the other side being away from the pixel opening, is S, wherein S < 5 µm.

9. The display panel according to claim 6, wherein the second defining structure comprises a first end adjacent to the third defining structure, the third defining structure comprises a second end adjacent to the second defining structure, and a spacing between a side edge of the first end that is proximal to the pixel opening and a side edge of the second end that is proximal to the pixel opening is L, wherein L < 2 µm.

10. The display panel according to claim 1, wherein a material of the third defining structure is a hydrophobic material.

11. The display panel according to claim 1, wherein a portion of the bank structure located between adjacent pixel openings comprises a plurality of the accommodation openings, and the plurality of accommodation openings are arranged surrounding the pixel opening.

12. The display panel according to claim 11, wherein the plurality of accommodation openings are arranged surrounding the pixel opening, and a shape of an orthographic projection of an inner wall of the accommodation opening on the substrate is circular or polygonal, or the shape of the orthographic projection of the inner wall of the accommodation opening on the substrate is a preset pattern, wherein the preset pattern comprises two oppositely disposed and mutually parallel first straight sides and two oppositely disposed and mutually parallel second curved sides, with a length direction of the first straight sides being parallel to an arrangement direction of adjacent pixel openings.

13. The display panel according to claim 11, wherein one or more of the plurality of accommodation openings are located between pixel openings adjacent along the second direction.

14. The display panel according to claim 11, wherein the accommodation opening extending along the first direction is provided penetratingly along the first direction such that both ends of the accommodation opening respectively extend beyond the corresponding pixel opening.

15. The display panel according to claim 1, wherein a cross-sectional shape of the defining structure in a plane perpendicular to the substrate is an inverted trapezoid, and a base angle of the inverted trapezoid is a, wherein 90° ≤ a ≤ 150°;
or a cross-sectional shape of the defining structure in the plane perpendicular to the substrate is a regular trapezoid, triangle, or quadrilateral.

16. The display panel according to claim 1, wherein the first functional layer comprises a first portion and a second portion discontinuously provided, the first portion being located within the pixel opening, the second portion being located within the accommodation opening, and the second functional layer comprises a third portion and a fourth portion discontinuously provided, the third portion being located within the pixel opening, the fourth portion being located within the accommodation opening.

17. The display panel according to claim 16, wherein the first functional layer comprises at least one of a hole injection layer, a hole transport layer, and an electron blocking layer; and the second functional layer comprises at least one of a hole blocking layer, an electron transport layer, and an electron injection layer.

18. The display panel according to claim 1, wherein the limiting structure has an inverted trapezoidal cross-sectional shape perpendicular to a plane where the substrate is located, the display panel further comprises an encapsulation layer, the encapsulation layer comprises a plurality of encapsulation portions spaced apart, the encapsulation portions contact sidewalls of the pixel openings, and an orthographic projection of the encapsulation portions on the substrate covers an orthographic projection of the light-emitting layer on the substrate; the display panel further comprises a second electrode, the second electrode is located on a side of the second functional layer away from the substrate, adjacent second electrodes are spaced apart, and an orthographic projection of the second electrode on the substrate covers the pixel openings.

19. The display panel according to claim 1, wherein a partial area of the first electrode is exposed by the pixel opening, and an orthographic projection of the limiting structure on the substrate covers edge portions of an orthographic projection of the first electrode on the substrate.

20. A display device, comprising:
a substrate;
a first electrode layer, located on one side of the substrate and comprising a plurality of spaced first electrodes;
a first functional layer, a light-emitting layer, and a second functional layer sequentially stacked in a direction away from the substrate, the light-emitting layer comprising a plurality of light-emitting structures; and
a bank structure, comprising a defining structure, a plurality of pixel openings provided in the defining structure and accommodating the plurality of light-emitting structures, and an accommodation opening provided in the defining structure and located between adjacent light-emitting structures, the accommodation opening being configured to accommodate a portion of the first functional layer located between adjacent pixel openings and a portion of the second functional layer located between adjacent pixel openings, and the first functional layer and the second functional layer within the accommodation opening being in direct contact.
